(19) United States
(12) Patent Application Publication
(10) Pub. No.: US 2026/0231296 A1
(43) Pub. Date: Aug. 6, 2026

(54) METHODS AND SYSTEMS FOR REDUCTION OF THERMAL GRADIENT ACROSS HEIGHT OF A VESSEL

(71) Applicant: ASM IP Holding B.V., Almere (NL)

(72) Inventor: Matthew Ricketts, Scottsdale, AZ (US)

(21) Appl. No.: 19/461,847

(22) Filed: Jan. 28, 2026

Related U.S. Application Data
(60) Provisional application No. 63/752,149, filed on Jan. 31, 2025.

(51) Int. Cl. H05B 1/02; H05B 3/06

(52) U.S. Cl. CPC H05B 1/0233; H05B 3/06

(57) ABSTRACT

Various embodiments of the present technology provide a system including a conductive plate having a first bore and a second bore disposed therein, a first heating element disposed in the first bore and a second heating element disposed in the second bore, the first bore disposed in a first quadrant of the conductive plate and the second bore disposed in a second quadrant of the conductive plate, the first quadrant meeting the second quadrant only at a center of the conductive plate.

### CROSS-REFERENCE TO RELATED APPLICATIONS

This application is a nonprovisional of, and claims priority to and the benefit of, U.S. Provisional Patent Application No. 63/752,149, filed Jan. 31, 2025 and entitled “METHODS AND SYSTEMS FOR REDUCTION OF THERMAL GRADIENT ACROSS HEIGHT OF A VESSEL,” which is hereby incorporated by reference herein.

### FIELD

The present disclosure generally relates to a method and system for semiconductor equipment. More particularly, the present disclosure relates to methods and systems for reduction of thermal gradient across a height of a vessel.

### BACKGROUND

During various industrial processes, including thin film deposition processes, a vessel is heated, within which the industrial process occurs. Often, depending upon the industrial process, it is beneficial for there to be little to no thermal gradient between the top and the bottom of the vessel.

### SUMMARY

Various embodiments of the present technology provide a system comprising a conductive plate having a first bore and a second bore disposed therein, a first heating element disposed in the first bore and a second heating element disposed in the second bore, the first bore disposed in a first quadrant of the conductive plate and the second bore disposed in a second quadrant of the conductive plate, the first quadrant meeting the second quadrant only at a center of the conductive plate.

Various embodiments of the present technology provide a method comprising machining aluminum into a conductive plate, boring a first bore and a second bore into the conductive plate, disposing a first swaged heating cartridge into the first bore; and disposing a second swaged heating cartridge into the second bore.

According to one aspect, a system comprises: a reactor comprising an inlet and an outlet; a first vessel comprising a first inlet and a first outlet coupled to the inlet of the reactor; a second vessel comprising a second inlet and a second outlet coupled to the inlet of the reactor; and an exhaust line coupled to the outlet of the reactor, the first inlet of the first vessel, and the second inlet of the second vessel; wherein the first and second vessels are configured to receive a vapor though the exhaust line and recondense the vapor into a solid material.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a vessel system in accordance with embodiments of the present technology;

FIG. 2 representatively illustrates a heating system in accordance with embodiments of the present technology;

FIG. 3 representatively illustrates the heating system of FIG. 2 with partial transparency of certain components, in accordance with embodiments of the present technology; and

FIG. 4 representatively illustrates the heating system of FIG. 2 with partial transparency of certain components, in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various vessels, reaction chambers, piping, pumps, valves, and heating elements.

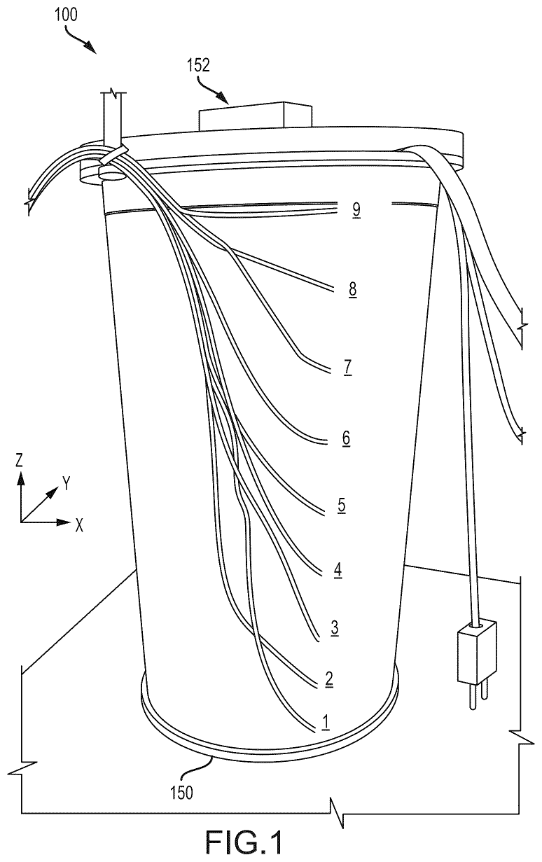

Referring to FIG. 1, a vessel system 100 may comprise a process vessel 102, a heating system 150 and a heating system 152. Vessel system 100 is illustrated with reference to an XYZ coordinate system, with the X-direction extending longitudinally and the Z-direction extending vertically with respect to the process vessel 102. Process vessel 102 may comprise a circular cross section (i.e., along the xy plane). Distance along the z axis is referred to herein as “height” of the process vessel 102. To measure thermal gradient across the height of process vessel 102, thermocouples 1, 2, 3, 4, 5, 6, 7, 8, and 9 may be affixed to process vessel 102. Though thermocouples 1, 2, 3, 4, 5, 6, 7, 8, and 9 are illustrated as equidistant from one another, these thermocouples may be placed at any desired distance from one another. It is desirable that the temperature data received from each of thermocouples 1, 2, 3, 4, 5, 6, 7, 8, and 9 reflects a low standard deviation from the arithmetic mean (i.e., average). Stated another way, it is desirable for there to be little to no difference in the temperature data reported by thermocouples 1, 2, 3, 4, 5, 6, 7, 8, and 9. In this manner, heating system 150 may be used to heat the bottom of process vessel 102 while heating system 152 heats the top of process vessel 102.

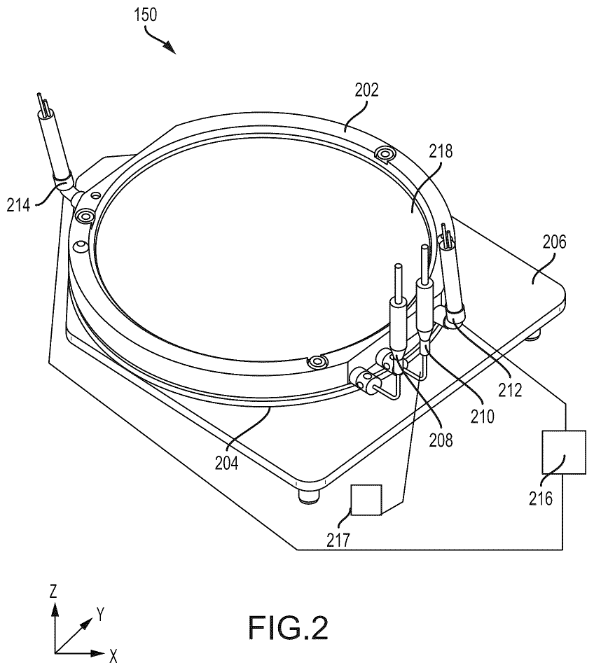

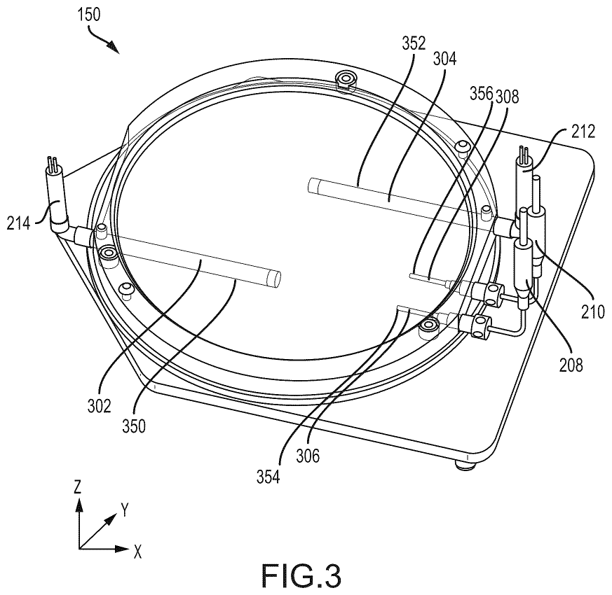

With reference to FIGS. 2 and 3, heating system 150 is illustrated. FIG. 3 shows heating system 150 with partial transparency for illustrative purposes. Heating system 150 comprises conductive plate 202 and insulating plate 204.

Insulating plate 204 is configured to contact conductive plate 202, being disposed beneath (i.e., in the negative z direction) conductive plate 202. Insulating plate 204 may comprise any suitable thermally insulating material. For example insulating plate 204 may comprise polymeric materials, thermoplastics, thermoset, metal and/or metal alloys, fibrous materials, or other suitable materials. In various embodiments, insulating plate 204 comprises at least one of polyetherimide (e.g. PEI), acrylonitrile butadiene styrene, nylon, polylactic acid, polybenzimidazole, polycarbonate, polyether ether ketone, and/or other polymeric materials. Insulating plate 204 may comprise an inset portion configured to mate with conductive plate 202.

Conductive plate 202 is configured to at least partially contact process vessel 102. Indentation 218 in conductive plate 202 allows process vessel 102 to rest on conductive plate 202. Conductive plate 202 may be comprised of any suitable metal or metal alloy. For example, conductive plate 202 may comprise aluminum, aluminum alloys, titanium, titanium alloys, iron, irons alloys (including steel), copper, copper alloys, and any other suitable metal or metal alloys. In various embodiments, conductive plate 202 comprises International Alloy Designation System 6000 series aluminum alloy (aluminum-magnesium-silicon alloys), International Alloy Designation System 7000 series aluminum (aluminum-zinc alloys), grade 5 titanium (also known as Ti6Al4V, which contains titanium, aluminum, and vanadium), grade 2 titanium (also known as commercially pure titanium as set forth in ASTM SB-265), copper, brass, and/or bronze.

In various embodiments, conductive plate 202 comprises first bore 350 and second bore 352. First bore 350 and second bore 352 are bores and/or channels disposed in conductive plate 202 that at least partially traverse conductive plate 202. FIG. 3 illustrates first bore 350 and second bore 352. First bore 350 and second bore 352 may be drilled, milled, machined, or otherwise cut into conductive plate 202. To the extent conductive plate 202 is additively manufactured, first bore 350 and second bore 352 may be integrated into the design during additive manufacturing. First bore 350 and second bore 352 may be of any suitable size and configured to receive heating element 302 and heating element 304.

Heating element 302 and heating element 304 are disposed in first bore 350 and second bore 352, respectively. Heating element 302 and heating element 304 may comprise any device capable of producing heat and/or conducting heat to conductive plate 202. Heating element 302 and heating element 304 may function as conductive or convective heaters. In various embodiments, heating element 302 and heating element 304 are resistive heating elements, namely swaged heating cartridges. Swaged heating cartridges are typically constructed as cylinders that produce heat through electrical resistance.

Heating element 302 and heating element 304 may thus have wires connecting heating element 302 and heating element 304 to at least one of a power supply and/or controller 216. Heating element connector 212 and heating element connector 214 may comprise a rigid or semirigid housing through which wires may be run to connect heating element 302 and heating element 304 to at least one of a power supply and/or controller 216.

Control thermocouple 306 and safety thermocouple 308 are disposed in secondary bore 354 and secondary bore 356, respectively. Control thermocouple 306 and safety thermocouple 308 may comprise any suitable device capable of measuring temperature. For example, control thermocouple 306 and safety thermocouple 308 may comprise thermocouples, which produce a temperature dependent voltage signal. Secondary bore 354 and secondary bore 356 may be drilled, milled, machined, or otherwise cut into conductive plate 202. To the extent conductive plate 202 is additively manufactured, secondary bore 354 and secondary bore 356 may be integrated into the design during additive manufacturing. Secondary bore 354 and secondary bore 356 may be of any suitable size and configured to receive control thermocouple 306 and safety thermocouple 308.

Control thermocouple 306 and safety thermocouple 308 may have wires routed through thermocouple control connector 208 and thermocouple safety connector 210, respectively. These wires may connect control thermocouple 306 and safety thermocouple 308 to at least one of a power supply and/or controller 216. Safety thermocouple 308 may be routed to a controller other than controller 216, such as controller 217 in various embodiments, for redundancy purposes. Stated another way, safety thermocouple 308 may interact with an controller 217 to form a redundant safety control path.

Controllers 216 and 217 may be implemented as and may include one or more processors and/or one or more tangible, non-transitory memories and be capable of implementing logic. Each processor can be a general purpose processor, a digital signal processor (DSP), an application specific integrated circuit (ASIC), a field programmable gate array (FPGA) or other programmable logic device, discrete gate or transistor logic, discrete hardware components, or any combination thereof. The controllers 216 and 217 may comprise a processor configured to implement various logical operations in response to execution of instructions, for example, instructions stored on a non-transitory, tangible, computer-readable medium (i.e., the memory) configured to communicate with the controllers 216 and 217. Furthermore, any number of conventional techniques for electronics configuration, signal processing and/or control, data processing and the like may be employed. Also, the processes, functions, and instructions may can include software routines in conjunction with processors, or the like.

Controller 216 may comprise and/or be instructed to retain a temperature setpoint (also referred to as a predetermined desired temperature). Controllers 216 and 217 may receive temperature data from control thermocouple 306 and safety thermocouple 308, respectively. Controller 216 may receive temperature data from control thermocouple 306. Control thermocouple 306, being disposed within conductive plate 202, is in thermal contact with conductive plate 202 and thus may be used to measure the temperature of conductive plate 202. In response to temperature information received from control thermocouple 306, controller 216 may modulate current applied to heating elements 302 and 304. Stated another way, controller 216 may increase, decrease, and/or maintain current applied to heating elements 302 and 304 to effect heating of conductive plate 202. Controller 216 may comprise a proportional-integral-derivative (PID) controller and/or a proportional-integral (PI) controller. In this manner, controller 216 may modulate heating elements 302 and 304 to achieve a near steady state temperature of conductive plate 202. Controller 216 may be configured to modulate current to heating elements 302 and 304 in any suitable manner. In this regard, current may be applied continuously or periodically to obtain the desired thermal characteristics of conductive plate 202.

Controller 217 may comprise and/or be instructed to retain a temperature safety setpoint (also referred to as a predetermined safety temperature). Controller 217 may receive temperature data from safety thermocouple 308. Safety thermocouple 308, being disposed within conductive plate 202, is in thermal contact with conductive plate 202 and thus may be used to measure the temperature of conductive plate 202. In response to temperature information received from safety thermocouple 308 indicating that the temperature of the conductive heating plate 202 is above the temperature safety setpoint, controller 217 may stop current from being applied to heating elements 302 and 304. Stated another way, controller 217 may command a cessation of current applied to heating elements 302 and 304. In this manner, controller 217 may act as an independent control pathway that is able to prevent overheat of conductive plate 202.

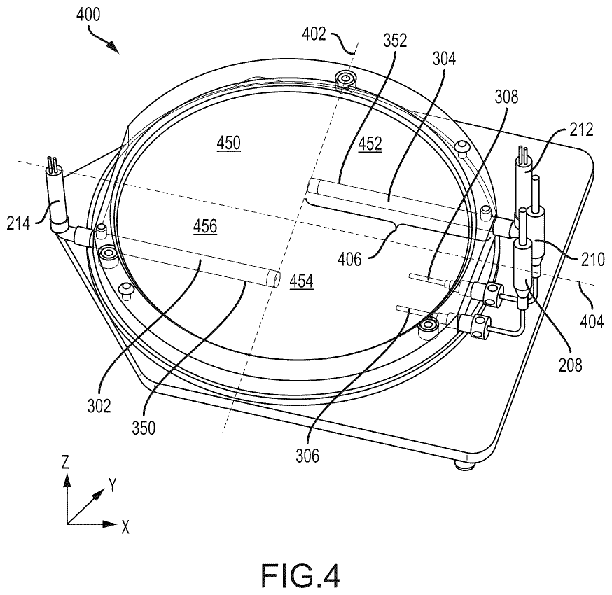

With reference to FIG. 4, heating system 150 is illustrated. Diameter 402 is depicted being perpendicular to diameter 404. Both diameter 404 and diameter 402 pass through the center of the conductive plate 202 and divide conductive plate 202 into quadrants. As illustrated, quadrant 452, quadrant 454, and quadrant 456 are shown. Each quadrant represents on quarter (25%) of the total cross-sectional surface area of conductive plate 202. Quadrant 450 touches quadrant 454 only at the center of conductive plate 202. Quadrant 456 only touches quadrant 452 in the center of conductive plate 202. It is beneficial that there be a uniform and/or substantially uniform heating across the cross-sectional surface area of conductive plate 202, meaning uniform or substantially uniform heat in the XY plane. To achieve this, it is helpful to have heating elements 302 and 304 disposed in a manner that is likely to encourage such heat distribution. Thus, heating element 302 may be disposed in a quadrant that only touches the quadrant housing heating element 304 at the center of conductive plate 202. As illustrated, heating element 302 is disposed in quadrant 456 and heating element 304 is disposed in quadrant 452. Moreover, heating element 302 extends to diameter 402 but not beyond. In the same manner, heating element 304 extends to diameter 402, but not beyond. In various embodiments, heating elements may not necessarily extend to a diameter of the conductive plate 202 and may fall short of reaching the diameter. In various embodiments, however, there may be a heating element disposed in each quadrant of conductive plate 202. It should be understood that first bore 350 and second bore 352 may extend beyond diameter 402, though in various embodiments, the length of heating element 302 and 304 is the same or less than the length of first bore 350 and second bore 352, respectively. In this manner, the length of first bore 350 and/or second bore 352 may be less than the radius of conductive plate 202.

Regarding construction of heating system 150, in various embodiments, a metal or metal alloy, as described above, may be machined and/or additively manufactured in to conductive plate 202. In that regard, aluminum may be machined into a cylindrical or substantially cylindrical structure to form conductive plate 202. A first bore and a second bore may be bored into the conductive plate 202. Such boring may be performed by a drill or mill and/or through electrical discharge manufacturing (EDM). A first swaged heating cartridge maybe disposed into the first bore and a second swaged heating cartridge maybe disposed into the second bore. The swaged heating cartridges may then be placed into electrical communication with a controller. An insulating plate 204 may be injection molded and/or machined of a thermoplastic, such as polyetherimide. The insulating plate 204 may then be coupled to conductive plate 202.

### Example 1

Vessel system 100 was operated by using heating system 152 only while heating system 150 was not powered. Heating system 152 was configured for a setpoint of 82° C. After a predetermined warmup time, temperature measurements were taken from thermocouples 1-6 and 9. The results are shown in TABLE 1.

TABLE 1

| | Temperature |
|---|---|
| Thermocouple | in ° C. |
| 9 | 82.9 |
| 6 | 83 |
| 5 | 79.3 |
| 4 | 78 |
| 3 | 74.4 |
| 2 | 71 |
| 1 | 65.5 |
| Average (Mean) | 76.3 |
| Std. Dev. | 5.7 |
| Range | 17.5 |

### Example 2

Vessel system 100 was operated by using heating system 152 and heating system 150. Heating system 152 was configured in the same manner was in Example 1. Heating system 150 and heating system 152 were configured with a setpoint of 77° C. After a predetermined warmup time, temperature measurements were taken from thermocouples 101-109. The results are shown in TABLE 2.

TABLE 2

| | Temperature |
|---|---|
| Thermocouple | in ° C. |
| 9 | 78.75 |
| 8 | 78.6 |
| 7 | 78.55 |
| 6 | 78.33 |
| 5 | 78.21 |
| 4 | 77.78 |
| 3 | 77.52 |
| 2 | 77.52 |
| 1 | 77.49 |
| Average (Mean) | 78.08 |
| Std. Dev. | 1.1 |
| Range | 1.3 |

As illustrated, the use of heating system 150 and heating system 152 produced a much smaller standard deviation and range relative to the use of heating system 152 alone. In this manner, the temperature of process vessel 102 was significantly more uniform in EXAMPLE 2 than in EXAMPLE 1.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. A system, comprising:
a conductive plate having a first bore and a second bore disposed therein; and
a first heating element disposed in the first bore and a second heating element disposed in the second bore, the first bore disposed in a first quadrant of the conductive plate and the second bore disposed in a second quadrant of the conductive plate, the first quadrant meeting the second quadrant only at a center of the conductive plate.

2. The system of claim 1, wherein the first heating element comprises a swaged cartridge heater and the second heating element comprises a second swaged cartridge heater.

3. The system of claim 1, further comprising a secondary bore in the conductive plate, wherein a control thermocouple is disposed in the secondary bore.

4. The system of claim 3, further comprising an additional secondary bore in the conductive plate, wherein a safety thermocouple is disposed in the additional secondary bore.

5. The system of claim 4, wherein the secondary bore and the additional secondary bore are disposed in a third quadrant of the conductive plate, the third quadrant being different from the first quadrant and the second quadrant.

6. The system of claim 5, a controller in electrical communication with the first heating element, the second heating element, the safety thermocouple and the control thermocouple.

7. The system of claim 6, wherein the controller is configured to receive temperature data from the control thermocouple and to modulate current to at least one of the first heating element or the second heating element based upon the temperature data.

8. The system of claim 7, wherein the controller is configured to receive second temperature data from the safety thermocouple and, in response to the second temperature data exceeding a predetermined threshold temperature, commanding cessation of current applied to the first heating element and the second heating element.

9. The system of claim 1, wherein the first bore has a length less than a radius of the conductive plate.

10. The system of claim 9, wherein the first bore is parallel from the second bore.

11. The system of claim 1, further comprising an insulating plate in contact with the conductive plate.

12. The system of claim 10, wherein the first bore is a first distance from a diameter of the conductive plate.

13. The system of claim 12, wherein the second bore is a second distance from the diameter of the conductive plate, the first distance being equal to the second distance.

14. The system of claim 13, wherein the conductive plate comprises a second diameter perpendicular to the diameter, wherein the first bore extends to the second diameter.

15. The system of claim 13, wherein the conductive plate comprises an aluminum alloy.

16. A vessel configured to couple to the system of claim 1.

17. A method comprising:
machining aluminum into a conductive plate;
boring a first bore and a second bore into the conductive plate;
disposing a first swaged heating cartridge into the first bore; and
disposing a second swaged heating cartridge into the second bore.

18. The method of claim 17, wherein the boring comprises boring the first bore in a first quadrant of the conductive plate and the second bore in a second quadrant of the conductive plate, the first quadrant meeting the second quadrant only at a center of the conductive plate.

19. The method of claim 18, further comprising boring a secondary bore and an additional secondary bore into the conductive plate.

20. The method of claim 19, coupling an insulating plate to the conductive plate.
